(19) United States
(12) Patent Application Publication
(10) Pub. No.: US 2016/0211447 A1
(43) Pub. Date: Jul. 21, 2016

(54) CONDUCTIVE BRIDGING MEMORY DEVICE HAVING A CU-TE-(GE/SI) COMPRISING TOP ELECTRODE

(71) Applicants: IMEC VZW, Leuven (BE); Universiteit Gent, Gent (BE)

(72) Inventors: Wouter Devulder, Leuven (BE); Ludovic Goux, Leuven (BE); Karl Opsomer, Leuven (BE)

(73) Assignees: IMEC VZW, Leuven (BE); Universiteit Gent, Gent (BE)

(21) Appl. No.: 14/995,488

(22) Filed: Jan. 14, 2016

(30) Foreign Application Priority Data
Jan. 15, 2015 (EP) 15151265.4

(51) Int. Cl. H01L 45/00

(52) U.S. Cl. CPC H01L 45/144; H01L 45/1233

(57) ABSTRACT

A Conductive Bridge Random Access Memory (CBRAM) device is disclosed, comprising an insulating electrolyte element sandwiched between a cation supply electrode and a bottom electrode, whereby the cation supply electrode consists of a CuₓZ_{y}eTe_{z} alloy with Z being Ge or Si and with y>15 at. %.

### CROSS-REFERENCE TO RELATED APPLICATIONS

The present application is a non-provisional patent application claiming priority to European Patent Application No. 15151265.4 filed Jan. 15, 2015, the contents of which are hereby incorporated by reference.

### FIELD OF THE DISCLOSURE

The present disclosure relates to Conductive Bridging Random Access Memory devices, also known as CBRAM devices. In particular, the present disclosure relates to a CBRAM device having a top electrode comprising Cu, Te, and (Ge or Si).

### BACKGROUND

The Conductive Bridging Random Access Memory (CBRAM) device is considered as a valuable non-volatile storage technology. It offers fast switching, high endurance, low voltage and good scalability.

A CBRAM device contains an insulating layer sandwiched between an active electrode providing metal cations, e.g. Cu+ or Ag+, and an inert electrode. The operation of the CBRAM device relies on the voltage-induced redox-based formation and rupture of a Cu- or Ag-based conical shaped conductive filament (CF) in the insulating layer acting as a solid state electrolyte. When an electrical field is applied between both electrodes, Cu- or Ag cations provided by the active electrode will drift towards the opposite inert electrode through the insulating layer thereby forming the conductive filament in the electrolyte. As such, the CBRAM device can be reversibly switched between a high resistive (HRS) or reset state and a low resistive (LRS) or set state.

Some CBRAM devices, such as those having a Cu-containing active electrode, may have poor retention properties. Retention is the stability of respectively both the LRS and the FIRS state and may relate to the lifetime of the device at an elevated temperature. A typical specification is a lifetime of 10 years at, depending on the application, a temperature of 50° C., 85° C. or even up to 150° C.

One method to improve the retention of the LRS state only, i.e. the stability of the formed metallic CF, is to engineer an electrolyte element in which the Cu—CF will not dissolve. Examples of such electrolytes are oxides, such as GdO₂ or Al₂O₃, resulting in a LRS retention of the CBRAM device higher than if chalcogenide electrolytes are used.

Another method to partly improve the retention of a CBRAM device is to engineer an appropriate active electrode that supplies Cu-ions. CBRAM devices having a Cu active electrode exhibit a poor FIRS retention. By adding Te to the Cu active electrode, the FIRS stability is increased, however at the expense of a reduced LRS stability. This reduced stability effect was attributed to the chemical affinity between Cu and Te, which favors the Cu back-diffusion from the CF towards the Cu—Te supply element. By incorporating Ge into the Cu—Te containing active electrode, a trade-off can be made between the thermal stability of the LRS and the FIRS states.

These prior art devices however showed a decreased performance when subjected to elevated temperatures.

Hence, there is a need for a CBRAM device that does not exhibit the shortcomings of the conventional CBRAM devices.

### SUMMARY

A Conductive Bridge Random Access Memory (CBRAM) device is disclosed comprising an insulating electrolyte element sandwiched between a cation supply metal electrode and a bottom electrode. The cation supply metal electrode (3) comprises a CuₓZ_{y}Te_{z} alloy, with Z being Ge or Si and with 0<x, y, z<100 at. %, whereby y>15 at. %.

In an example embodiment including a CuₓGe_{y}Te_{z} alloy, the ratio Cu/(Cu+Te) of the alloy may range from 0.4 and 0.77, i.e. 0.4≦x/(x+z)≦0.77.

Within this range x, y, and z are determined to have a CuₓGe_{y}Te_{z} alloy having a mono-phase crystalline structure. In an example embodiment, this mono-phase crystalline structure is a CuₓGe_{y}Te_{z} alloy with a composition x=33 at. %, y=17 at. % and z=50 at. %.

Within this range, x, y, and z are determined to have a CuₓGe_{y}Te_{z} alloy with an amorphous structure. In an example embodiment, this amorphous structure is a CuₓGe_{y}Te_{z} alloy with a composition x=50 at. %, y=35 at. % and z=15 at. %. In another embodiment, this amorphous structure is a CuₓGe_{y}Te_{z} alloy with a composition x=48 at. %, y=20 at. % and z=32 at. %.

Within this range, x, y, and z are determined to have a CuₓSi_{y}Te_{z} alloy with an amorphous structure. In an example embodiment, this amorphous structure is a CuₓSi_{y}Te_{z} alloy with a composition x=48 at. %, y=20 at. % and z=32 at. %.

### BRIEF DESCRIPTION OF THE FIGURES

For the purpose of teaching, drawings are added. These drawings illustrate some aspects and embodiments of the disclosure. They are only schematic and non-limiting. The size of some of the elements may be exaggerated and not drawn on scale for illustrative purposes. The dimensions and the relative dimensions do not correspond to actual reductions to practice of the disclosure. Like features are given the same reference number.

FIG. 1 illustrates a CBRAM device according to an example embodiment.

FIGS. 2(a) to 2(d) show electrical characterizations of 580 μm diameter Pt/CuₓTe_{y}Ge_{z}/Al₂O₃/Si dot cells with a Cu₂GeTe₃ supply layer (active electrode) according to example embodiments. More particularly, FIG. 2(a) shows I-V curves; FIG. 2(b) plots Low Resistance states (LRS: bottom, circles) and High Resistance states (HRS: top, squares) over 200 subsequent cycles; FIG. 2(c) plots LRS (bottom, squares I_{c} of 100 μA, diamond I_{c} of <100 μA) and FIRS (top, circles I_{c} of 100 μA) as a function of time at 85° C.; and FIG. 2(d) plots the electrical resistance after 121.6 h of baking at 85° C. as a function of resistance after programming: LRS (bottom left, squares I_{c} of 100 μA, diamond I_{c} of <100 μA) and HRS (top right, circles I_{c} of 100 μA).

FIGS. 3(a) to 3(c) show electrical characterizations of 580 μm diameter Pt/CuₓTe_{y}Ge_{z}/Al₂O₃/Si dot cells with a Cu—Te—Ge supply layer (active electrode) with a large amorphous window according to example embodiments of this disclosure. More particularly, FIG. 3(a) shows I-V curves; FIG. 3(b) plots Low Resistance States (LRS: bottom, squares I_{c} of 100 μA, diamond I_{c} of 10 μA) and High Resistance States (HRS: top, circles I_{c} of 100 μA) as a function of time at 85° C.; and FIG. 3(c) plots the electrical resistance after 121.6 h baking at 85° C. as a function of resistance after programming: LRS (bottom left, squares I_{c} of 100 μA, diamond I_{c} of <100 μA) and HRS (top right, circles I_{c} of 100 μA).

FIG. 4 illustrates an amount of Ge (at. %) as function of the ratio Cu/(Cu+Te) in the cation metal supply electrode according to an example embodiment.

FIGS. 5(a) to 5(c) show electrical characterizations of 580 μm diameter Pt/CuₓSi_{y}Ge_{z}/Al₂O₃/Si dot cells with a Cu—Te—Si supply layer (active electrode) with large amorphous window according to this disclosure. More particularly, FIG. 5(a) shows curves; FIG. 5(b) plots Low Resistance States (LRS: bottom, squares I_{c} of 100 μA, diamond I_{c} of 50 μA) and High Resistance States (HRS: top, circles I_{c} of 100 μA) as function of time at 85° C.; and FIG. 5(c) plots the electrical resistance after 121.6 h baking at 85° C. as a function of resistance after programming: LRS (bottom left, squares I_{c} of 100 μA, diamond I_{c} of 50 μA) and HRS (top right, circles I_{c} of 100 μA).

### DETAILED DESCRIPTION

The present disclosure will be described with respect to particular embodiments and with reference to certain drawings but the disclosure is not limited thereto. Furthermore, the terms first, second and the like in the description, are used for distinguishing between similar elements and not necessarily for describing a sequence, either temporally, spatially, in ranking or in any other manner. It is to be understood that the terms so used are interchangeable under appropriate circumstances and that the embodiments of the disclosure described herein are capable of operation in other sequences than described or illustrated herein. Moreover, the terms top, under and the like in the description are used for descriptive purposes and not necessarily for describing relative positions. It is to be understood that the terms so used are interchangeable under appropriate circumstances and that the embodiments of the disclosure described herein are capable of operation in other orientations than described or illustrated herein.

The present disclosure relates to a CBRAM device (1) with improved thermal stability. The CBRAM device has an active electrode (3) containing Cu and Te, whereby this electrode (3) is further alloyed with Si or Ge.

In an example embodiment, a CBRAM device is disclosed that comprises an active electrode (3) comprising Cu, Ge and Te, whereby the active electrode (3) has an improved thermal stability.

Conventional Cu—Ge—Te active electrodes may include a microstructure of this (Cu,Ge,Te)-alloy. However, such active electrodes may be thermally unstable. At elevated temperatures, these conventional Cu—Ge—Te alloys suffer from, amongst other issues, phase separation or undesired crystallization. Such effects may lead to more roughened surfaces, which may reduce reproducibility and may cause the device to malfunction. Due to such thermal instability, the further manufacturing of the CBRAM device once the active electrode is formed, may be impacted. For example, the thermal budget allowed during the Back-End-Of-Line (BEOL) processing when establishing an electrical interconnect to the CBRAM device may depend, at least in part, on the thermal instability of the active electrode. This instability jeopardizes the programming properties of the finished CBRAM device. Additionally, thermal instability makes improving the retention of both the LRS and the HRS more difficult. For example, a non-uniformity might be introduced between CBRAM devices due to this thermal instability. The affinity between the conductive filament and the active electrode (supply layer) may vary locally if the microstructure of the active electrode is not uniform due to different bonding configuration of Cu electrode with the alloying elements Te and Ge. Hence the HRS and LRS stability may be non-uniform from cell to cell.

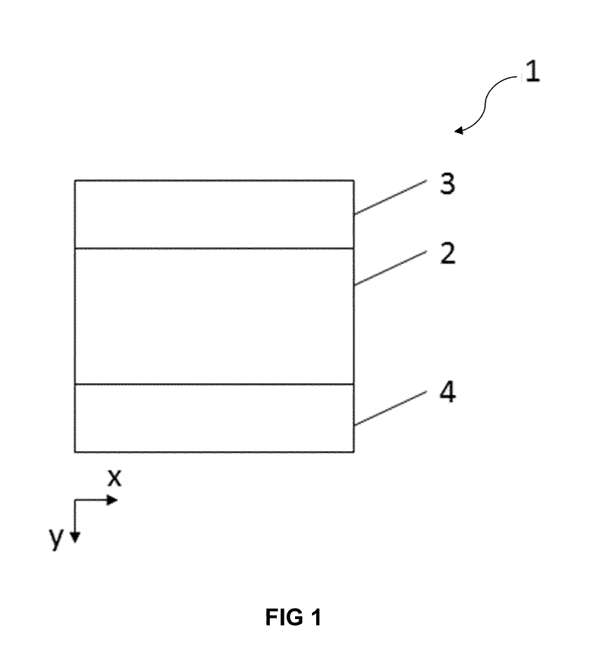

Such CBRAM device is illustrated in FIG. 1. Here a Conductive Bridge Random Access Memory (CBRAM) device (1) is shown comprising an insulating electrolyte element (2) sandwiched between a cation supply metal electrode (3) and a bottom electrode (4). The bottom electrode (4) is labelled ‘inert’ as it doesn't provide cations during the filament (11) forming process. The cation supply metal electrode (3), also referred to as active electrode (3), comprises a (Cu, Ge, Te)-alloy that is thermally stable, and may include a homogeneous composition and structure, e.g. being amorphous or having a mono- or polycrystalline phase.

In an example embodiment, the cation supply electrode (3) comprises Cu, Ge and Te, thereby supplying Cu⁺ cations during programming of the CBRAM device (1). The cation supply metal electrode (3) comprises a CuₓGe_{y}Te_{z} alloy, with 0<x, y, z<100 at. %, whereby y>15 at. %.

In a first embodiment, the cation supply electrode (3) consists of a Cu₂Ge₁Te₃ alloy: Cu₃₃Ge₁₇Te₅₀. Initially formed as an amorphous layer, its composition favors a single type of chemical binding between Cu and the alloying elements Te and Ge. After crystallization, typically at a temperature of about 200° C., this Cu—Ge—Te alloy exhibits a single stable phase up to the typical temperatures applied during the BEOL processing, i.e. temperatures between 350° C. and 450° C. Back-End-Of-Line (BEOL) processing refers the process steps establishing an electrical interconnect to the CBRAM device. These process steps include the formation of at least one metallic interconnect pattern separated by one or more dielectric layers, whereby openings in the dielectric layers allows electrically contacting the underlying CBRAM device and, if present, additional metallic interconnect patterns above. Alloys having another Cu—Ge—Te composition segregate into different crystal phases during such BEOL processing. Such segregations are not desired and may for example lead to non-uniform device properties. Retention properties were demonstrated for a CBRAM device having such Cu₂GeTe₃ alloy being at least comparable to conventional CBRAM devices having a Cu or Cu₆Te₄ cation supply electrode (3), but with an improved uniformity due, at least in part, to the homogenous alloy structure.

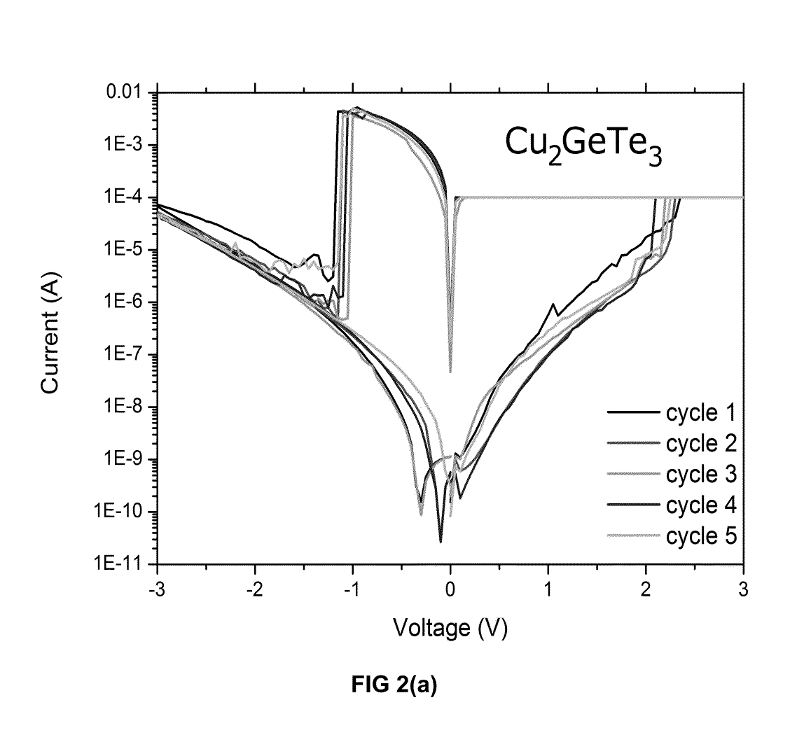

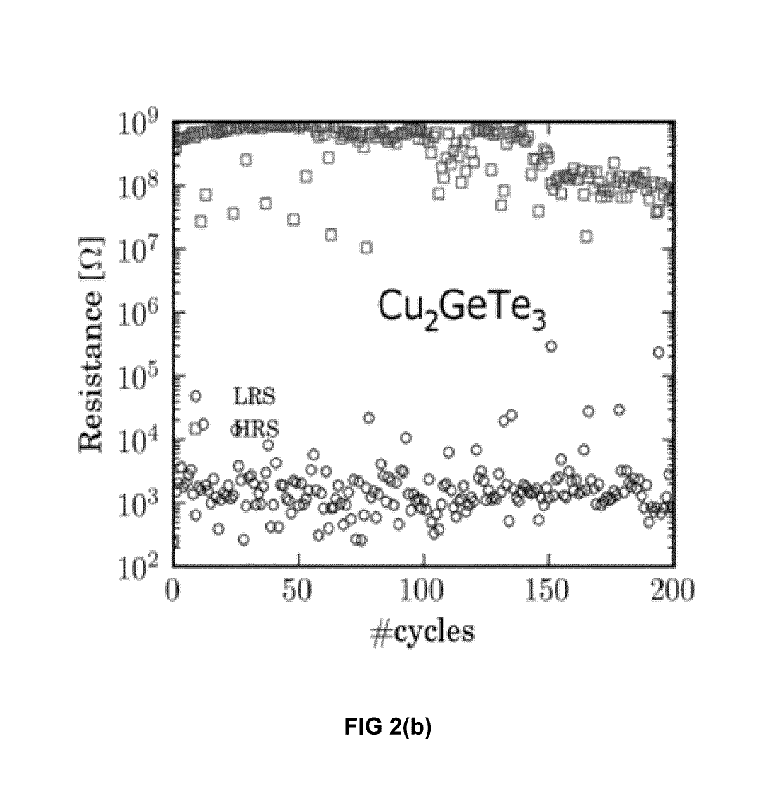

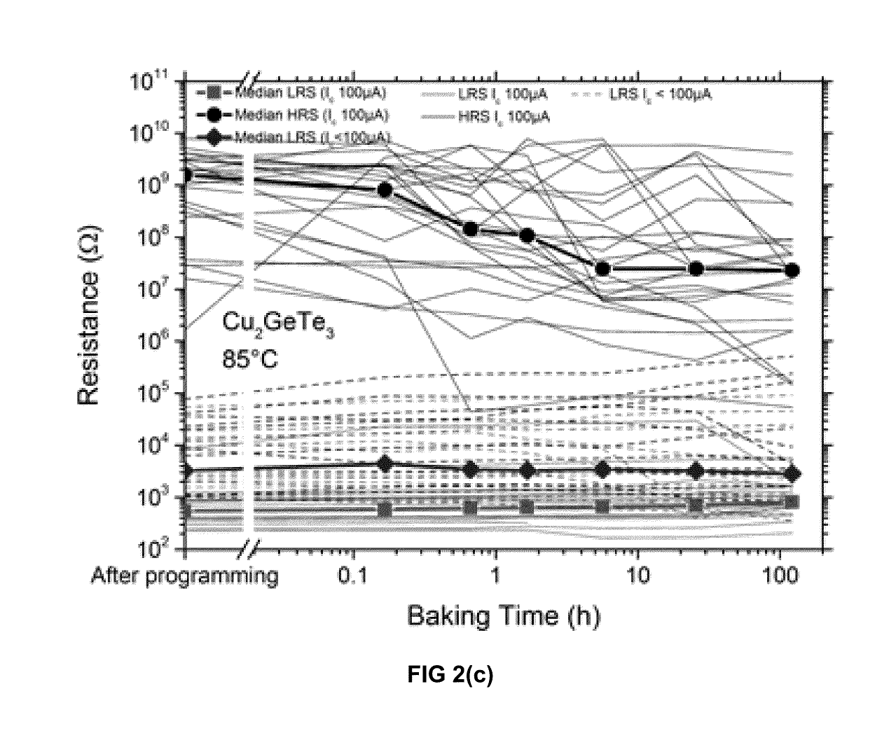

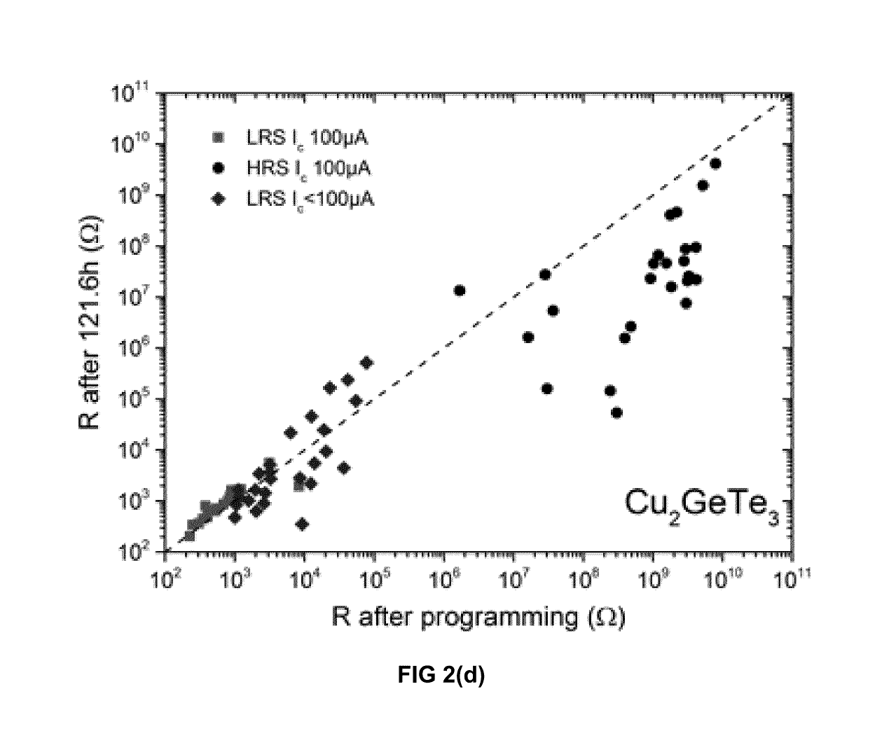

In an example embodiment, a 50 nm Pt/50 nm Cu-supply layer is deposited by sputter deposition through a 580 μm dot shadow mask onto a 3 nm Al₂O₃ layer. The Al₂O₃ layer in turn is deposited by an H₂O based ALD process on n-doped Si. FIGS. 2a to 2d show the electrical characterization of these 580 μm diameter Pt/CuₓTe_{y}Ge_{z}/Al₂O₃/Si dot cells with a Cu₂GeTe₃ supply layer (active electrode) according to this disclosure. FIG. 2(a) shows the DC I-V curves. FIG. 2(b) shows the Low Resistance state (LRS: open circles) and High Resistance state (HRS: open squares) over 200 subsequent cycles. The macroscopic cells may be cycled at least 100 times. FIG. 2(c) shows HRS as function of time at 85° C., programmed using of 100 μA and the LRS as function of time at 85° C., programmed using I_{c} of 100 μA or less. The resistance of all measured memory cells is shown and their median value (solid symbols) after every anneal step at 85° C. The current in the set operation was limited (current compliance I_{c}) to 100 μA to avoid overgrown filaments. FIG. 2(d) shows the electrical resistance after 121.6 h baking at 85° C. as function of resistance after programming. As shown in FIG. 2(d), cells were also programmed with I_{c}<100 μA to get more cells in a LRS having higher resistance values (10 kΩ<R<100 kΩ), their resistance is also plotted. It can be seen that these cells also stay in their as programmed state. The mono phase Cu₂GeTe₃ composition showed an acceptable retention. It is observed that the FIRS is still the weak state, while a very stable LRS is present (also for 10 kΩ<R_{LRS}<100 kΩ). However, a resistive window of 4 orders of magnitude of the median resistance values is still present after 121.6 h baking at 85° C.

In a second embodiment, the cation supply electrode (3) comprises a CuₓGe_{y}Te_{z} alloy whereby the composition is selected to yield an alloy that remains amorphous over a larger temperature window, such as up to the temperatures selected for the BEOL processing, which processing temperatures are typically below 500° C. or below 400° C.

In an example of this second embodiment, the ratio (Cu/Te)>1. Such an alloy is referred to as a Te-poor (Cu,Ge,Te)-alloy. In an example embodiment, this alloy has a composition of Cu₅₀Ge₃₅Te₁₅. By reducing the amount of Te in the alloy, the crystallization temperature of the CuₓGe_{y}Te_{z} alloy may be increased, for example, to about 300° C. If the temperatures applied during the BEOL processing is below this crystallization temperature, i.e. below 300° C., the alloy will remain amorphous during the BEOL processing. This may prevent phase separation as the formation of different crystal phases will occur at higher temperatures. Good quality retention characteristics were demonstrated for compositions where ratio (Cu/Te)>1.

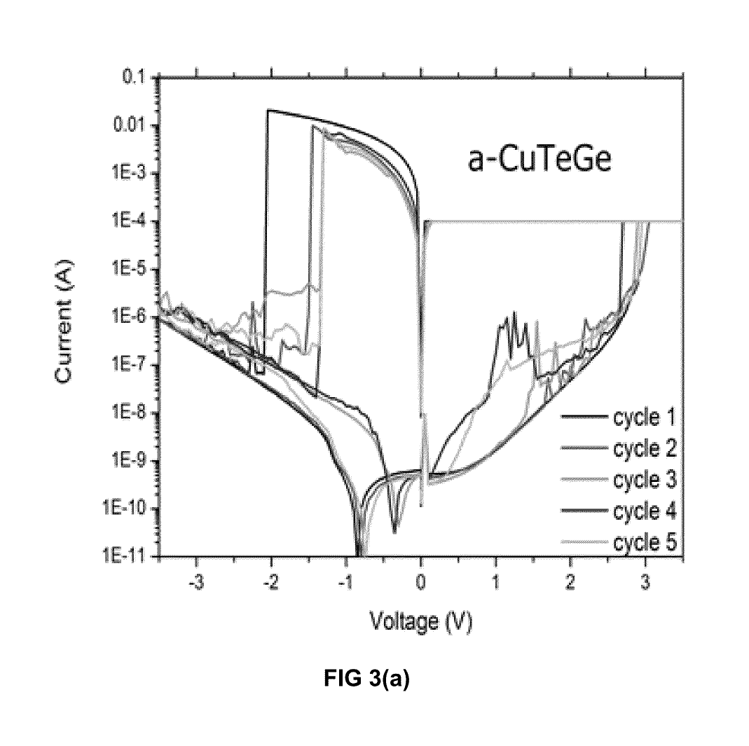

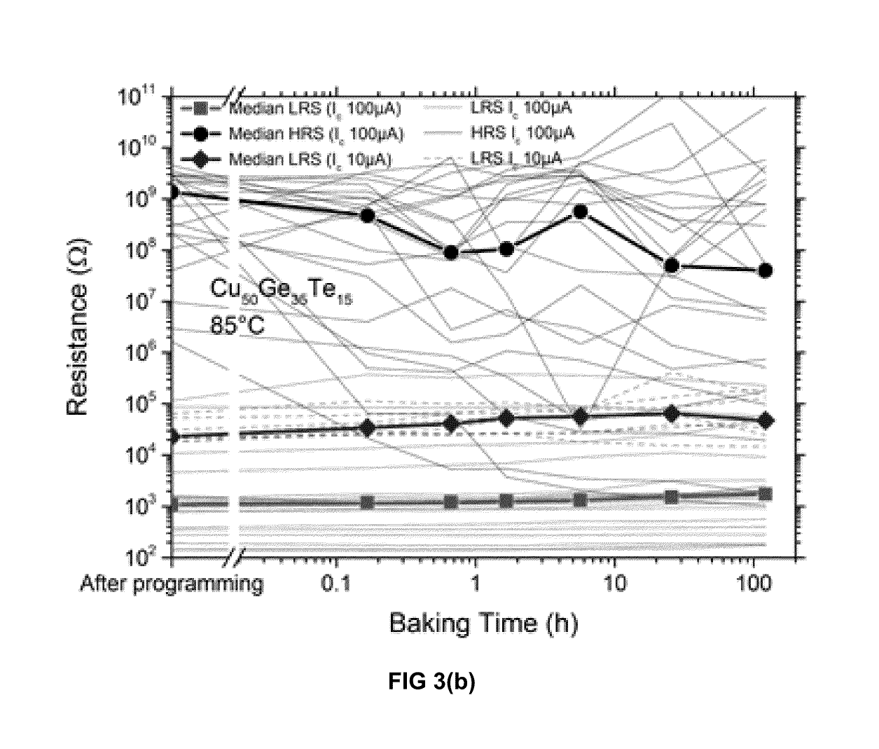

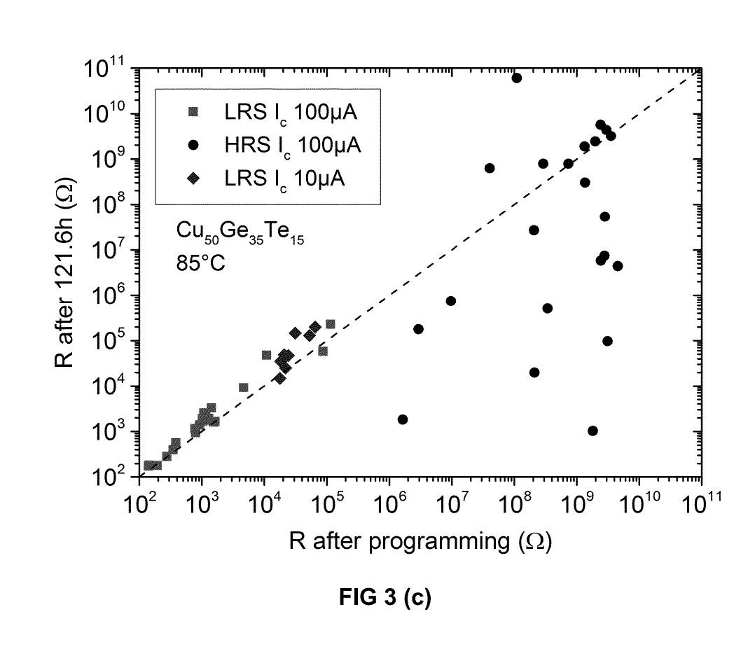

In an example embodiment, a 50 nm Pt/50 nm Cu-supply layer is deposited by sputter deposition through a 580 μm dot shadow mask onto a 3 nm Al₂O₃ layer, which in turn is deposited by an H₂O based ALD process on n-doped Si. FIGS. 3a to 3c show the electrical characterization of 580 μm diameter Pt/CuₓTe_{y}Ge_{z}/Al₂O₃/Si dot cells with a Cu—Te—Ge supply layer (active electrode) with large amorphous window according to this disclosure. FIG. 3(a) shows the I-V curves. FIG. 3(b) shows High Resistance State (HRS) as function of time at 85° C., programmed using I_{c} of 100 μA, and the LRS as function of time at 85° C., programmed using I_{c} of 100 μA or 10 μA. The current in the set operation is limited (current compliance I_{c}) to 100 μA to avoid overgrown filaments. The resistance of all measured memory cells is shown and their median value (solid symbols) after every anneal step at 85° C. FIG. 3(c) shows the electrical resistance after 121.6 h baking at 85° C. as function of resistance after programming. As shown in FIG. 3(c), cells were also programmed with 10 μA to get more cells in a LRS having higher resistance values (10 kΩ<R<100 kΩ), their resistance is also plotted. It can be seen that these cells also stay in their as programmed state. The composition with the large amorphous temperature window is attractive form materials viewpoint and also showed an acceptable retention. It is observed that the HRS is still the weak state, while a very stable LRS is present (also for 10 kΩ<R_{LRS}<100 kΩ). However, a resistive window of 4 orders of magnitude of the median resistance values is still present after 121.6 h baking at 85° C.

In another example embodiment, the cation supply electrode (3) comprises a CuₓGe_{y}Te_{z} alloy, whereby the ratio (Cu/Te) ratio can be in the range of (50/35) to (50/40). In one example, this alloy has a composition Cu₄₈Ge₂₀Te₃₂. By increasing the amount of Te in the alloy, the crystallization temperature of the CuₓGe_{y}Te_{z} alloy is reduced, for example, to about 200° C. If the temperatures applied during the BEOL processing are below this crystallization temperature, i.e. below 200° C., this alloy will remain again amorphous during the BEOL processing. This prevents phase separation because the formation of different crystal phases will generally take place at higher temperatures.

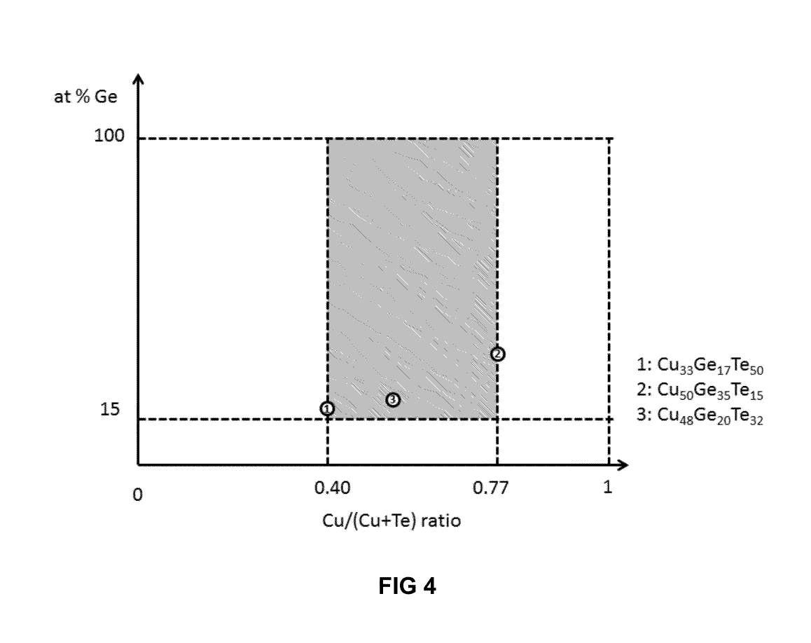

FIG. 4 shows the amount of Ge (at. %) as function of the ratio Cu/(Cu+Te) in the cation metal supply electrode (3). The grey area illustrates the CuₓGe_{y}Te_{z} alloys, with 0<x, y, z<100 at. %, whereby y>15 at. % according to this disclosures. In an example embodiment, the ratio Cu/(Cu+Te) is between 0.4 and 0.77 as shown by the grey area. The examples discussed in the foregoing paragraphs are indicated.

As discussed elsewhere herein, the CuTe cation supply electrode (3) may be alloyed to yield an alloy that remains amorphous over a larger temperature window, such as up to the temperatures selected for the BEOL, which processing temperatures are typically below 500° C. or below 400° C.

The inventors had found that using Si as alloying element to the CuTe cation supply electrode (3), in a device as illustrated in FIG. 1, results in an CuₓSi_{y}Te_{z} electrode (3) that remains amorphous over an even larger temperature window compared to a CuₓGe_{y}Te_{z} alloy

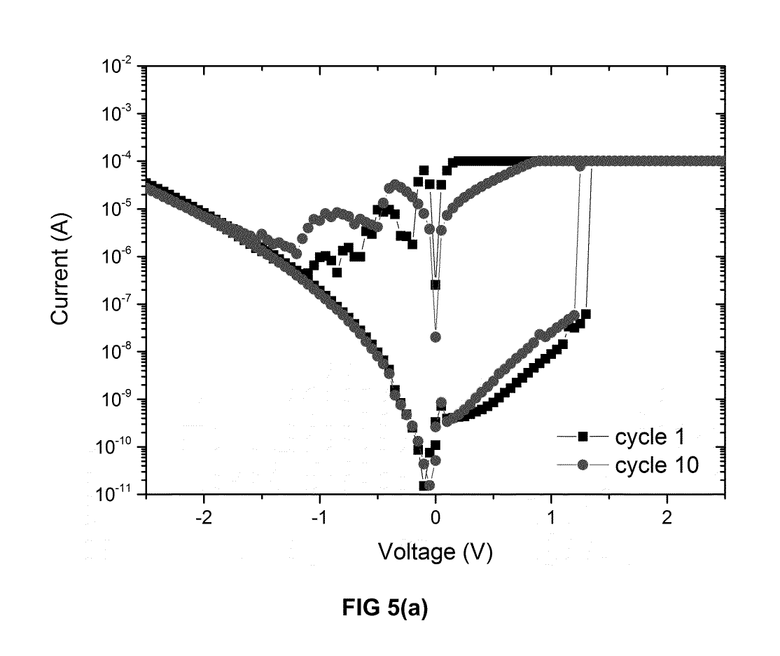

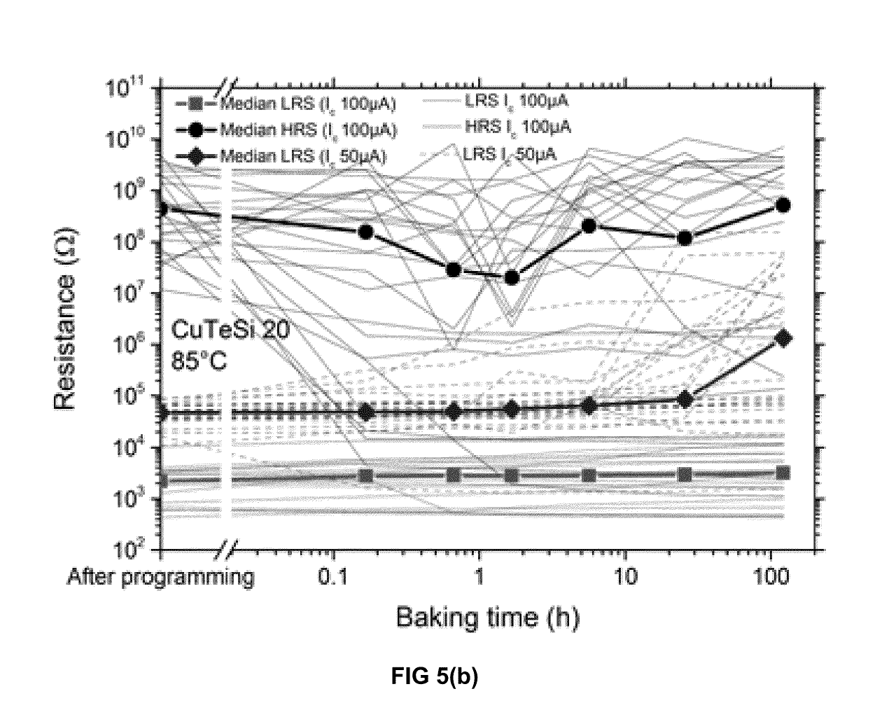

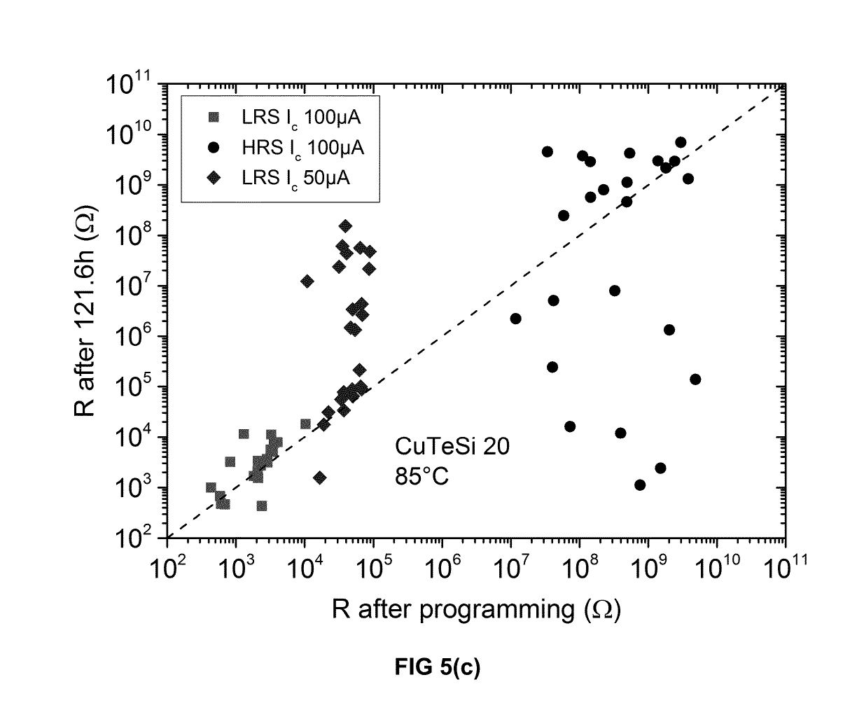

In an example embodiment, such an amorphous electrode may be obtained by a CuₓSi_{y}Te_{z} alloy with a composition x=48 at. %, y=20 at. % and z=32 at. %. Similar to the embodiments illustrated by FIGS. 2(a) to 2(d) and 3(a) to 3(c), FIGS. 5(a) to 5(c) shows the electrical characterization of 580 μm diameter Pt/CuₓSi_{y}Ge_{z}/Al₂O₃/Si dot cells with a Cu—Te—Si supply layer (active electrode) with large amorphous window according to this disclosure. FIG. 5(a) shows the I-V curves, i.e. the switching characteristics. FIG. 5(b) shows the Low Resistance State (LRS: bottom, squares I_{c} of 100 μA, diamond I_{c} of 50 μA) and High Resistance State (HRS: top, circles I_{c} of 100 μA) as function of time at 85° C. FIG. 5(c) shows the electrical resistance after 121.6 h baking at 85° C. as function of resistance after programming: LRS (bottom left, squares I_{c} of 100 μA, diamond I_{c} of 50 μA) and HRS (top right, circles I_{c} of 100 μA).

In an example embodiment, the dielectric material of insulating electrolyte element (2) may be selected from the group of chalcogenides. This dielectric material can be selected from the group of mixed ionic-electronic conductors (MIEC), such as CeO, ZrO, Y₂O₃, Yttria Stabilized Zirconia (YSZ), characterized by their very high ionic conductivity. In an example embodiment, the dielectric material is selected from the group of alumina oxides, hafnium oxides, tantalum oxides, silicon oxides of silicon nitrides.

Optionally a metallic liner (not shown) may be formed. The metallic liner may separate the cation supply electrode (3) from the electrolyte element (2). This metallic liner may contain Ta or TiW, for example. The metallic liner may improve the adhesion between the Cu supply layer and the electrolyte. In addition, the metallic liner may reduce Cu migration into the electrolyte during the BEOL processing.

Typically the bottom electrode (4) comprises tungsten. In an example embodiment, the bottom electrode (4) is formed of tungsten.

What is claimed is:

1. A Conductive Bridge Random Access Memory (CBRAM) device comprising:
an insulating electrolyte element sandwiched between a cation supply metal electrode and a bottom electrode, wherein the cation supply metal electrode comprises an CuₓZ_{y}Te_{z} alloy, with Z being Si or Ge, and wherein 0<x, y, z<100 at. %, whereby y>15 at. %.

2. The device of claim 1, wherein Z is Ge and a ratio of Cu/(Cu+Te) ranges from 0.4 to 0.77 such that 0.4≦x/(x+z)≦0.77.

3. The device of claim 2, wherein the CuₓGe_{y}Te_{z} alloy comprises a mono-phase, crystalline structure.

4. The device of claim 3, wherein the CuₓGe_{y}Te_{z} alloy has a composition x=33 at. %, y=17 at. % and z=50 at. %.

5. The device of claim 2, wherein the CuₓGe_{y}Te_{z} alloy comprises an amorphous structure.

6. The device of claim 5, wherein the CuₓGe_{y}Te_{z} alloy has a composition x=50 at. %, y=35 at. % and z=15 at. %.

7. The device of claim 5, wherein the CuₓGe_{y}Te, alloy has a composition x=48 at. %, y=20 at. % and z=32 at. %.

8. The device of claim 1, wherein Z is Si and wherein the CuₓSi_{y}Te_{z} alloy has a composition x=48 at. %, y=20 at. % and z=32 at. %.
